(19) United States
(12) Patent Application Publication
(10) Pub. No.: US 2026/0026094 A1
(43) Pub. Date: Jan. 22, 2026

(54) SEMICONDUCTOR DEVICE AND FABRICATING METHOD THEREOF

(71) Applicant: Fujian Jinhua Integrated Circuit Co., Ltd., Quanzhou City (CN)

(72) Inventors: Huixian LAI, Quanzhou City (CN); Shurui Liu, Quanzhou City (CN)

(73) Assignee: Fujian Jinhua Integrated Circuit Co., Ltd., Quanzhou City (CN)

(21) Appl. No.: 19/000,637

(22) Filed: Dec. 23, 2024

(30) Foreign Application Priority Data
Jul. 17, 2024 (CN) 202410961881.7

(51) Int. Cl. H10D 84/83; H10D 84/01

(52) U.S. Cl. CPC H10D 84/837; H10D 84/0128; H10D 84/0135; H10D 84/016; H10D 84/8316

(57) ABSTRACT

The present disclosure provides a semiconductor device and a fabricating method thereof, including a source structure, a drain structure, a gate structure, a channel structure, a supporting layer and a gate dielectric layer. The source structure and the drain structure are stacked in a vertical direction, and the gate structure is disposed between the drain structure and the source structure. The channel structure is partially disposed in the gate structure and is connected the drain structure and the source structure. The supporting layer is disposed on a sidewall of the channel structure. The gate dielectric layer is partially disposed between the channel structure and the gate structure in a horizontal direction, and partially disposed between the supporting layer and the gate structure. Through the arrangement of the supporting layer, the channel length of the semiconductor device will be effectively shrunken, to improve the performance and operation of the semiconductor device.

### BACKGROUND OF THE INVENTION

### 1. Field of the Invention

The present disclosure relates to a semiconductor device and a fabricating method thereof, and more particularly, to a semiconductor device including a vertical channel structure and a fabricating method thereof.

### 2. Description of the Prior Art

The development of semiconductor integrated circuit technology progresses continuously and circuit designs in products of the new generation become smaller and more complicated than those of the former generation. The amount and the density of the functional devices in each chip region are increased constantly according to the requirements of innovated products, and the size of each device has to become smaller accordingly. The conventional planar metal-oxide-semiconductor (MOS) transistor has difficulty when scaling down in the development of the semiconductor device. Therefore, the stereoscopic transistor technology or the non-planar transistor technology that allows smaller size and higher performance is developed to replace the planar MOS transistor for reducing the dimension of the transistor unit and/or improving the operation performance of the transistor unit.

### SUMMARY OF THE INVENTION

One of the objectives of the present disclosure is to provide a semiconductor device where a supporting layer is additionally disposed on a sidewall of a channel structure, so that a gate dielectric layer enables to surround the gate structure, thereby improving the structural stability and the performance of the semiconductor device.

One of the objectives of the present disclosure is to provide a fabricating method of a semiconductor device, in which a channel structure is formed before forming the gate structure, and a supporting layer is additionally formed on a sidewall of the channel structure, so that, a gate dielectric layer formed subsequently enables to surround the gate structure, thereby forming the semiconductor device with a more stable structure and better performance.

To achieve the purpose described above, one embodiment of the present disclosure provides a semiconductor device includes a source structure, a drain structure, a gate structure, a channel structure, a supporting layer and a gate dielectric layer. The source structure and the drain structure are stacked in a vertical direction. The gate structure is disposed between the drain structure and the source structure. The channel structure is partially disposed in the gate structure and electrically connected the drain structure and the source structure. The supporting layer is disposed on a sidewall of the channel structure. The gate dielectric layer is partially disposed between the channel structure and the gate structure in a horizontal direction, and is partially disposed between the supporting layer and the gate structure.

To achieve the purpose described above, one embodiment of the present disclosure provides a fabricating method of a semiconductor device includes the following steps. A source structure, a gate structure and a drain structure are sequentially forming in a vertical direction. A channel structure is formed between the drain structure and the source structure, the channel structure being partially disposed in the gate structure and is electrically connected the drain structure and the source structure. A supporting layer is formed on a sidewall of the channel structure. A gate dielectric layer is formed between the channel structure and the gate structure, and the gate dielectric layer is further formed between the supporting layer and the gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic cross-sectional diagram illustrating a semiconductor device according to a first embodiment of the present disclosure.

FIG. 2 to FIG. 11 are schematic diagrams illustrating a fabricating method of a semiconductor device according to an embodiment of the present disclosure, wherein:

FIG. 2 is a schematic top view of a semiconductor device after forming a supporting material layer;

FIG. 3 is a schematic cross-sectional view of a semiconductor device after forming a supporting material layer;

FIG. 4 is a schematic top view of a semiconductor device after forming a channel opening;

FIG. 5 is a schematic cross-sectional view of a semiconductor device after forming a channel opening;

FIG. 6 is a schematic cross-sectional view of a semiconductor device after forming a channel structure;

FIG. 7 is a schematic cross-sectional view of a semiconductor device after removing a sacrificial layer;

FIG. 8 is a schematic cross-sectional view of a semiconductor device after forming an electrode material layer;

FIG. 9 is a schematic cross-sectional view of a semiconductor device after forming a gate structure;

FIG. 10 is a schematic top view of a semiconductor device after forming an insulating spacer; and

FIG. 11 is a schematic cross-sectional view of a semiconductor device after forming an insulating spacer.

FIG. 12 is a cross-sectional schematic diagram illustrating a semiconductor device according to a second embodiment of the present disclosure.

### DETAILED DESCRIPTION

To provide a better understanding of the presented invention, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

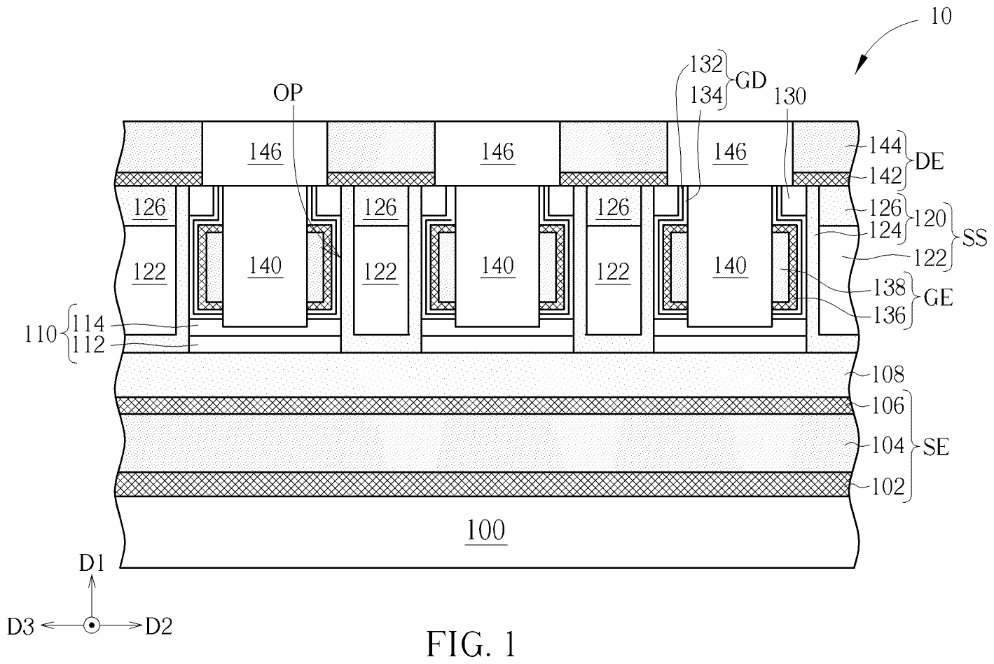

Please refer to FIG. 1. FIG. 1 is a schematic cross-sectional drawing illustrating a semiconductor device 10 according to a first embodiment of the present disclosure. As shown in FIG. 1, the semiconductor device 10 includes a source structure SE, a drain structure DE, a gate structure GE, a channel structure SS, a supporting layer 130, and a gate dielectric layer GD. The source structure SE and the drain structure DE are stacked in a vertical direction D1, and the gate structure GE is disposed on the source structure SE, between the drain structure DE and the source structure SE. The channel structure SS is partially disposed in the gate structure GE, and also between the drain structure DE and the source structure SE to electrically connect thereto.

It is noted that the supporting layer 130 is disposed on a portion of a sidewall of the channel structure SS, and the gate dielectric layer GD overlays the supporting layer 130, so that, a portion of the gate dielectric layer GD is disposed between the channel structure SS and the gate electrode GE in a horizontal direction D2/D3, and another portion of the gate dielectric layer GD is disposed between the supporting layer 130 and the gate electrode GE in the vertical direction D1. Through the arrangement of the supporting layer 130, the gate dielectric layer GD overlayed on the sidewall of the supporting layer 130 is allowable to surround the gate structure GE, thereby improving the structural stability of the gate structure GE and the channel structure SS, and enhancing the operation of the semiconductor device 10.

Precisely speaking, the semiconductor device 10 further includes a bottom dielectric layer 110 and an insulating spacer 140 sequentially disposed between the source structure SE and the gate structure GE, and which may include an insulating material being different from that of the supporting layer 130. In one embodiment, the bottom dielectric layer 110, the insulating spacer 140, and the supporting layer 130 for example include silicon oxide, silicon nitride, silicon oxynitride, silicon carbonitride, or other suitable insulating materials. For example, the insulating spacer 140 includes a material like silicon oxide, or silicon oxynitride, when the bottom dielectric layer 110 and the supporting layer 130 includes a material like silicon nitride or silicon carbonitride, but not limited thereto. In another embodiment, the supporting layer 130 may optionally include a material the same as that of the insulating spacer 140, like silicon oxide or silicon oxynitride. Preferably, the bottom dielectric layer 110 includes a first dielectric layer 112 and a second dielectric layer 114 stacked in sequence, and which may respectively include different insulating materials. The first dielectric layer 112 preferably includes a material the same as that of the insulating spacer 140, like silicon oxide, and the second dielectric layer 114 preferably includes a material the same as that of the supporting layer 130, like silicon nitride, but not limited thereto.

The gate structure GE is disposed in the insulating spacer 140, and a bottom of the insulating spacer 140 is further extended into the bottom dielectric layer 110, to obtain a bottom surface being lower than the gate dielectric layer GD. Then, the channel structure SS partially disposed in the gate structure GE is further disposed in the bottom dielectric layer 110 between the source structure SE and the gate structure GE, to obtain a bottom surface being coplanar with the bottom dielectric layer 110, as shown in FIG. 1. Accordingly, the arrangement of the gate dielectric layer GD enables to effectively isolate the gate electrode GE and the elements adjacent thereto, and to further improve the structure and the function thereof. It is noted that the gate dielectric layer GD physically contacts a top surface, a bottom surface and a sidewall of the gate structure GE at the same time, and also, further contacts a sidewall and a bottom surface of the supporting layer 130 at the same time, so that, the gate dielectric layer GD is partially disposed between the supporting layer 130 and the insulating spacer 140 in the horizontal direction D2/D3, and is partially disposed below the gate structure GE in the vertical direction D1, between the gate structure GE and the bottom dielectric layer 110. In other words, the gate dielectric layer GD substantially includes a spoon-shaped cross-section as shown in FIG. 1, to surround the gate structure GE. In one embodiment, the gate dielectric layer GD precisely includes a first gate dielectric layer 132 and a second gate dielectric layer 134 sequentially disposed between the channel structure SS and the gate structure GE, wherein the first gate dielectric layer 132 and the second gate dielectric layer 134 for example include different dielectric materials or different high-dielectric constant dielectric materials.

Further in view of FIG. 1, the semiconductor device 10 further includes a dielectric layer 100, a bottom semiconductor layer 108, a channel opening OP, and a top dielectric layer 146. The aforementioned elements including the source structure SE, the drain structure DE, the gate structure GE, the channel structure SS, the supporting layer 130 and the gate dielectric layer GD are all disposed on the dielectric layer 100, and the dielectric layer 100 is disposed on a substrate (not shown in the drawings) for example including a silicon substrate, a silicon-containing substrate, an epitaxial silicon substrate, a silicon-on-insulator substrate or a substrate being made by other suitable materials, but not limited thereto. People skilled in the arts should fully realize that any required active element or any passive element may be further formed either on the substrate or in the substrate, due to practical produce requirements, and which is not limited to be what is mentioned above.

Precisely speaking, the bottom semiconductor layer 108 is disposed between the source structure SE and the bottom dielectric layer 110 in the vertical direction D1, and the channel opening OP is penetrating through the supporting layer 130 and the bottom dielectric layer 110 in the vertical direction D1, to expose the bottom semiconductor layer 108 from the bottom of the channel opening OP. Then, the bottom surface of the channel structure SS disposed in the channel opening OP will physically contact the bottom semiconductor layer 108. The channel structure SS precisely includes a channel layer 120 and an insulating layer 122 stacked in sequence in the horizontal direction D2/D3, wherein the channel layer 120 further includes a first semiconductor layer 124 and a second semiconductor layer 126, and the insulating layer 122 may be used to indirectly control the composition of the channel structure SS and/or to support the channel structure SS.

The second semiconductor layer 126 is disposed between the insulating layer 122 and the drain structure DE in the vertical direction D1, and the first semiconductor layer 124 is around the second semiconductor layer 126 and the insulating layer 122 in the horizontal direction D2/D3, to include an U-shape cross section as shown in FIG. 1. In one embodiment, the bottom semiconductor layer 108, the first semiconductor layer 124, and the second semiconductor layer 126 for example all include a semiconductor material like doped polysilicon, doped amorphous silicon, indium zinc oxide (IZO), aluminum zinc oxide (AZO) or indium gallium zinc oxide (IGZO), but not limited thereto. Also, the materials of the first semiconductor layer 124, the second semiconductor layer 126 and the bottom semiconductor layer 108 may be optionally the same or different from each other. In another embodiment, the dielectric layer 100 and the insulating layer 122 for example both includes a dielectric material or a high-dielectric constant dielectric material, preferably both includes silicon oxide, but not limited thereto.

On the other hand, the top dielectric layer 146 is disposed on the insulating spacer 140, so that, the insulating spacer 140 is sandwiched between the bottom dielectric layer 110 and the top dielectric layer 146 in the vertical direction D1, and the drain structure DE is disposed in the top dielectric layer 146, but not limited thereto. Precisely speaking, the source structure SE, the gate structure GE, and the drain structure DE respectively include a multilayer structure. For example, the source structure SE preferably includes a barrier layer 102, a conductive layer 104, and a barrier layer 106 stacked sequentially in the vertical direction D1, the gate structure GE includes a barrier layer 136 and a gate layer 138 stacked sequentially in the horizontal direction D2/D3 on the gate dielectric layer GD, and the drain structure DE includes a barrier layer 142 and a conductive layer 144 stacked sequentially in the vertical direction D1, but is not limited thereto. In other embodiments, the barrier layer 102, the barrier layer 106, the barrier layer 136, and the barrier layer 142 for example include titanium (Ti), titanium nitride (TiN), tantalum (Ta), tantalum nitride (TaN), tungsten nitride (WN), or other suitable conductive barrier material, and the materials of the barrier layer 102, the barrier layer 106, the barrier layer 136 and the barrier layer 142 may be optionally the same or different from each other, preferably all including titanium nitride, but not limited thereto. Also, the conductive layer 104, the gate layer 138, and the conductive layer 144 all include copper, aluminum, tungsten or other suitable low-resistance metal materials, and the materials of the conductive layer 104, the gate layer 138, and the conductive layer 144 may be optionally the same or different from each other, preferably all including tungsten, but not limited thereto. In other embodiments, the barrier layer 102, the barrier layer 106, the barrier layer 136, and/or the barrier layer 142 may be optionally omitted or further include a multilayer, based on practical product requirements, but not limited thereto.

Through these arrangements, the channel structure SS of the semiconductor device 10 will present in a columnar structure extending in the vertical direction D1, physically contacting the second semiconductor layer 126 and the bottom semiconductor layer 108 through the first semiconductor layer 124 of the channel layer 120 at the same time, so that, the channel structure SS is allowable to be electrically connected to the drain structure DE and the source structure SE while a threshold voltage is applied to the gate structure GE. The drain structure DE, the gate dielectric layer GD, the gate structure GE, the channel structure SS, and the source structure SE may together form a three-dimensional (3D) transistor component, with the channel structure SS serving as the vertical channel structure of the 3D transistor component, and with the gate structure GE surrounding outside the channel structure SS to function like a gate-all-around (GAA). According to the semiconductor device 10 of the present embodiment, the supporting layer 130 is additionally disposed on the channel structure SS, such that, the gate dielectric layer GD overlaying the supporting layer 130 is between the gate structure GE and the channel structure SS in the horizontal direction D2/D3, and is partially between the supporting layer 130 and the gate structure GE and is partially between the gate structure GE and the bottom dielectric layer 110 in the vertical direction D1, to present a in spoon-shaped cross-section substantially. In this way, the gate dielectric layer GD is allowable to be disposed around the gate structure GE, to gain the improved structural stability and elemental functions to the gate structure GE and the channel structure SS, and also, the semiconductor device 10 will therefore obtain a relative shorter channel length, to gain the enhanced operation performance thereby.

In order to make people skilled in the art of the present disclosure easily understand the semiconductor device of the present disclosure, the fabricating method of the semiconductor device in the present disclosure will be further described below.

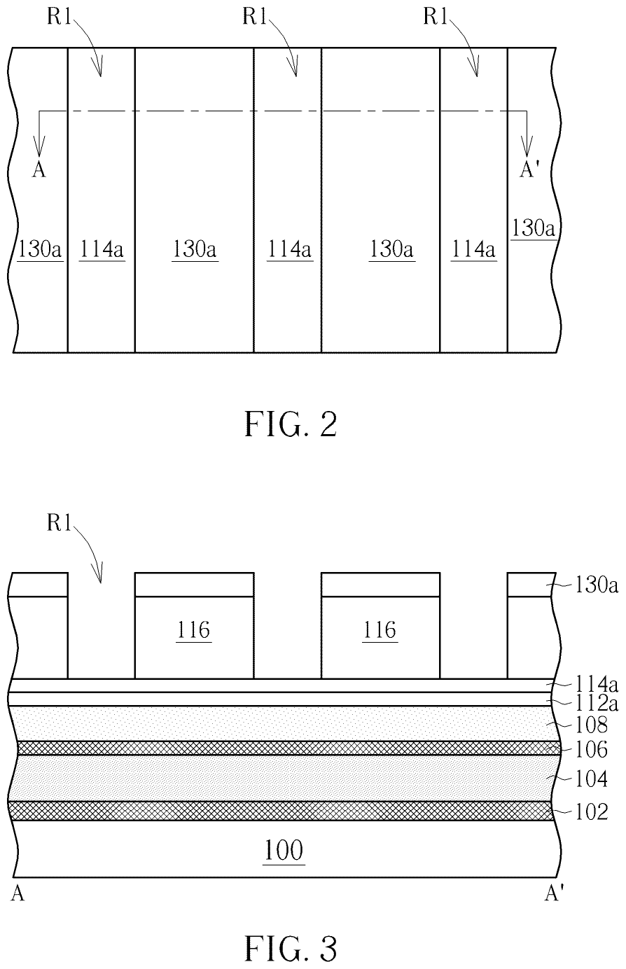

Please refer to FIG. 2 to FIG. 11, illustrating schematic diagrams of a fabricating method of the semiconductor device 10 according to one embodiment in the present disclosure. Firstly, as shown in FIG. 2 and FIG. 3, a film forming process is performed to sequentially form the source structure SE (including the barrier layer 102, the conductive layer 104 and the barrier layer 106 stacked in sequence), the bottom semiconductor layer 108, a first dielectric material layer 112a, a second dielectric material layer 114a, a sacrificial layer 116, and a supporting material layer 130a on the dielectric layer 100. Next, a through hole R1 is formed to penetrate through the supporting material layer 130a and the sacrificial layer 116, with the second dielectric material layer 114a being exposed from the bottom of the through hole R1. In one embodiment, the dielectric layer 100, the first dielectric material layer 112a, the second dielectric material layer 114a, the sacrificial layer 116, and the supporting material layer 130a for example all include a dielectric material like silicon oxide, silicon nitride, silicon oxynitride, or silicon carbonitride, or a high-dielectric constant dielectric material, with the dielectric layer 100, the first dielectric material layer 112a, and the sacrificial layer 116 preferably all including silicon oxide, and with the supporting material layer 130a and the second dielectric material layer 114a preferably all including a material different from that of the sacrificial layer 116, like silicon nitride, but not limited thereto. In another embodiment, the sacrificial layer 116 may optionally include silicon nitride, and the supporting material layer 130a and the second dielectric material layer 114a preferably include silicon oxide.

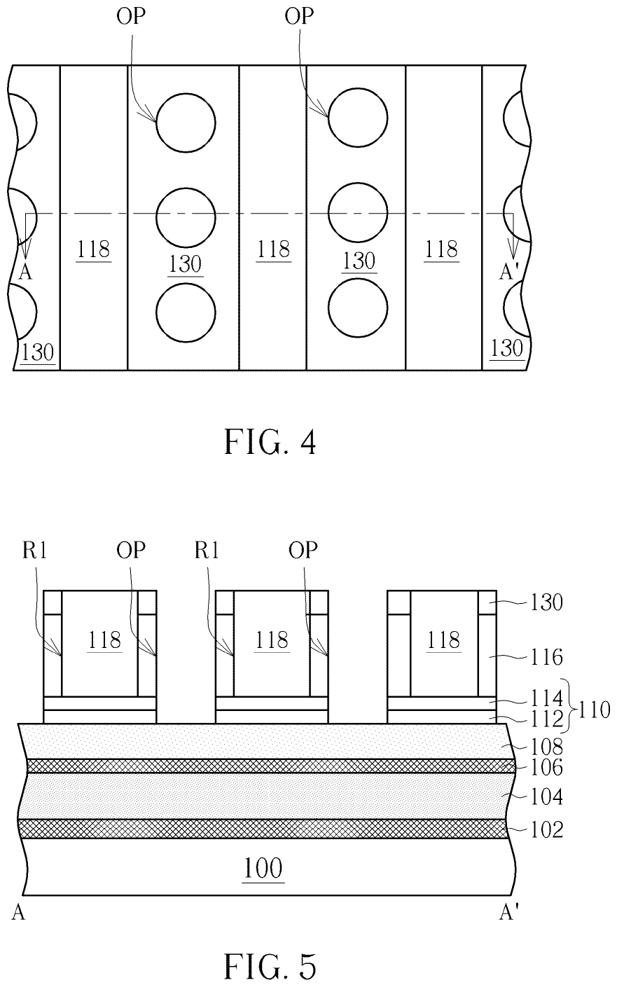

As shown in FIG. 4 and FIG. 5, another film forming process is performed to form a filling layer 118 in the through hole R1. Then, a dry etching process is performed through a mask (not shown in the drawings), to partially remove the supporting material layer 130a, the sacrificial layer 116, the first dielectric material layer 112a, and the second dielectric material layer 114a, to form at least one channel opening OP that penetrates through the supporting material layer 130a, the sacrificial layer 116, the first dielectric material layer 112a, and the second dielectric material layer 114a in the vertical direction D1, to expose the bottom semiconductor layer 108 from the bottom of the at least one channel opening OP. Also, while forming the at least one channel opening OP, the supporting layer 130 is formed on the external sidewall of the at least one channel opening OP, and the first dielectric layer 112 and the second dielectric layer 114 are sequentially formed between the bottom semiconductor layer 108 and the filling layer 118, followed by completely removing the mask. The first dielectric layer 112 and the second dielectric layer 114 together forms the bottom dielectric layer 110 of the semiconductor device 10. In one embodiment, the filling layer 118 for example includes a dielectric material being different from that of the supporting material layer 130a and the sacrificial layer 116, and preferably all including tetraethoxysilane (TEOS), but not limited thereto.

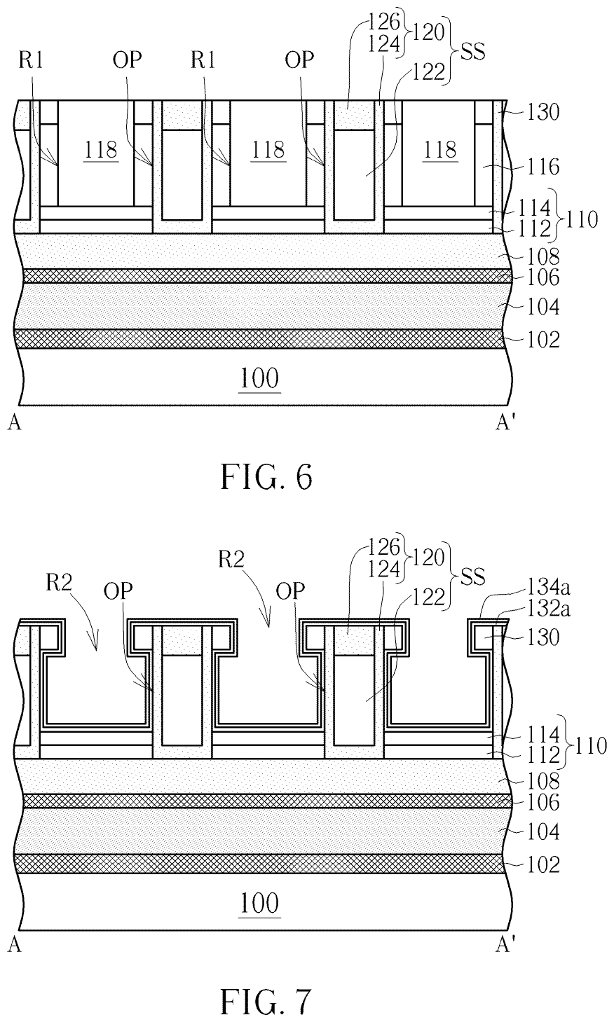

As shown in FIG. 6, the channel structure SS is formed within the at least one channel opening OP. The formation of the channel structure SS includes but not limited to the following steps. Firstly, a film forming process, such as a chemical vapor deposition process, a physical vapor deposition process or other suitable approaches, is further performed to form a first semiconductor material layer (not shown in the drawings) partially within the at least one channel opening OP, and partially outside the at least one channel opening OP, so that, the first semiconductor material layer will conformally overlay the top surfaces of the supporting layer 130 and the filling layer 118, and the sidewalls of the supporting layer 130, the sacrificial layer 116 and the bottom dielectric layer 110, physically contacting the bottom semiconductor layer 108, and then, an insulating material layer (not shown in the drawings) is formed to at least partially fill up the at least one channel opening OP. Next, the insulating material layer is partially removed to not fill up the at least one channel opening OP, to form the insulating layer 122 having the top surface being lower than the bottom surface of the supporting layer 130, and then a second semiconductor material layer (not shown in the drawings) is formed, to fill up the rest space of the at least one channel opening OP and to further overlay the top surfaces of the supporting layer 130 and the filling layer 118.

Then, performing a planarization process such as a chemical polishing process or other suitable approaches, to simultaneously remove the second semiconductor material layer and the first semiconductor material layer disposed outside the at least one channel opening OP, to form the second semiconductor layer 126 and the first semiconductor layer 124. Then, the second semiconductor layer 126, the insulating layer 122, and the first semiconductor layer 124 formed within the at least one channel opening OP together form the channel structure SS of the semiconductor device 10, with the supporting layer 130 being formed on the upper sidewall of the channel structure SS to have the top surface thereof being coplanar with the channel structure SS, as shown in FIG. 6. In one embodiment, the first semiconductor material layer and the second semiconductor material layer for example include a semiconductor material like doped polysilicon, doped amorphous silicon, indium zinc oxide, aluminum zinc oxide or indium gallium zinc oxide, preferably including the semiconductor material being the same as that of the bottom semiconductor layer 108, but not limited thereto. The insulating material layer for example includes a dielectric material like silicon oxide, silicon nitride, silicon oxynitride or silicon carbonitride, preferably including silicon oxide, but is not limited thereto.

As shown in FIG. 7, a wet etching process is performed, to simultaneously remove the filling layer 118 and the sacrificial layer 116 with similar etching selectivity, to form a through hole R2, to partially expose the second dielectric layer 114. Since the supporting layer 130 is formed on the upper sidewall of the channel structure SS, the through hole R2 will therefore obtain a smaller top and greater bottom diameter, present in a bottom-shaped cross-section as shown in FIG. 7, but not limited thereto. Also, a film forming process is performed to sequentially form a first gate dielectric material layer 132a and a second gate dielectric material layer 134a partially within the through hole R2 and partially outside the through hole R2. In one embodiment, the first gate dielectric material layer 132a and the second gate dielectric material layer 134a for example includes different dielectric materials or different high-dielectric constant dielectric material like silicon oxide, silicon nitride, silicon oxynitride, or silicon carbonitride, but not limited thereto.

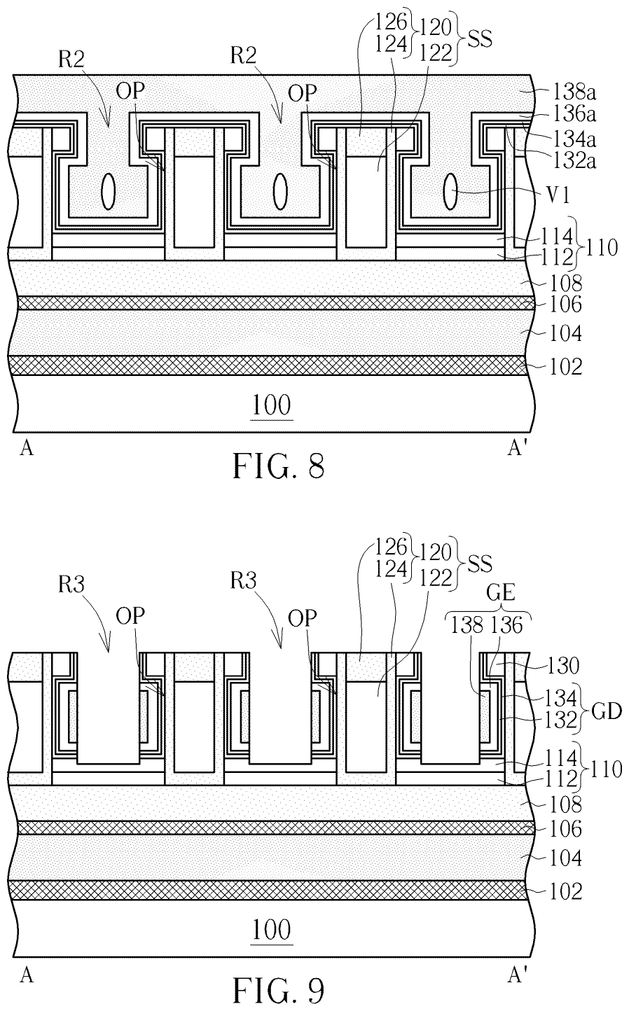

As shown FIG. 8, a barrier material layer 136a is formed partially within the through hole R2 and partially outside the through hole R2, and a conductive material layer 138a is then formed to fill up the through hole R2 and to further overlay the top surface of the supporting layer 130 and the channel structure SS. In one embodiment, through adjusting the processing conditions of forming the conductive material layer 138a and/or the aspect ratio of the through hole R2, a void V1 can be formed within the conductive material layer 138a, but not limited thereto. The void V1 formed within the conductive material layer 138a is for example lower than the bottom surface of the supporting layer 130, but is not limited thereto. In another embodiment, the barrier material layer 136a for example includes a barrier material like titanium, titanium nitride, tantalum, tantalum nitride, tungsten nitride, or other suitable barrier material, and the conductive material layer 138a for example includes copper, aluminum, tungsten or other low-resistance metal materials, but not limited thereto.

As shown in FIG. 9, a planarization process such as a chemical polishing process or other suitable approaches, to simultaneously remove the conductive material layer 138a, the barrier material layer 136a, the second gate dielectric material layer 134a, and the first gate dielectric material layer 132a formed outside the through hole R2, to expose the top surface of the supporting layer 130. Then, an etching process is performed through the supporting layer 130, to partially remove the conductive material layer 138a and the barrier material layer 136a, the second gate dielectric material layer 134a and the first gate dielectric material layer 132a formed at the bottom of the through hole R2, and the second dielectric layer 114 underneath, to form a through hole R3, with the bottom surface of the through hole R3 being lower than the bottom dielectric layer 110. Also, while forming the through hole R3, the barrier 136, the gate layer 138, the first gate dielectric layer 132, and the second gate dielectric layer 134 are simultaneously formed at two sides of the through hole R3. Accordingly, the barrier layer 136 and the gate layer 138 will together form the gate structure GE of the semiconductor device 10, and the first gate dielectric layer 132 and the second gate dielectric layer 134 will together form the gate dielectric layer GD of the semiconductor device 10. It is noted that, according to the fabricating method of the present disclosure, the channel structure SS with the cylinder-shaped cross-section is firstly formed in the vertical direction D1, and the supporting layer 130 is formed on the upper sidewall of the channel structures SS, followed by forming the gate dielectric layer GD and the gate structure GE. Through these performances, the formation of the gate structure GE is allowable to be carried out by performing an etching process directly through the supporting layer 130, instead of through a mask being formed additionally, and also, the gate dielectric layer GD formed subsequently will conformally overlap the supporting layer 130 and the lower sidewall of the channel structure SS, with the gate dielectric layer GD being formed around the gate structure GE to substantially present in a spoon-shaped cross-section as shown in FIG. 9. Then, the gate dielectric layer GD is formed after the channel structure SS is formed, to effectively avoid the possible structural damages, and to obtain an improved structural stability thereby. Furthermore, the gate dielectric layer GD is formed between the gate structure GE and the channel structure SS in the horizontal direction D2/D3, and partially between the supporting layer 130 and the gate structure GE, and partially between the gate structure GE and the bottom dielectric layer 110 in the vertical direction D1, to gain the better structural stability and device function to the gate structure GE.

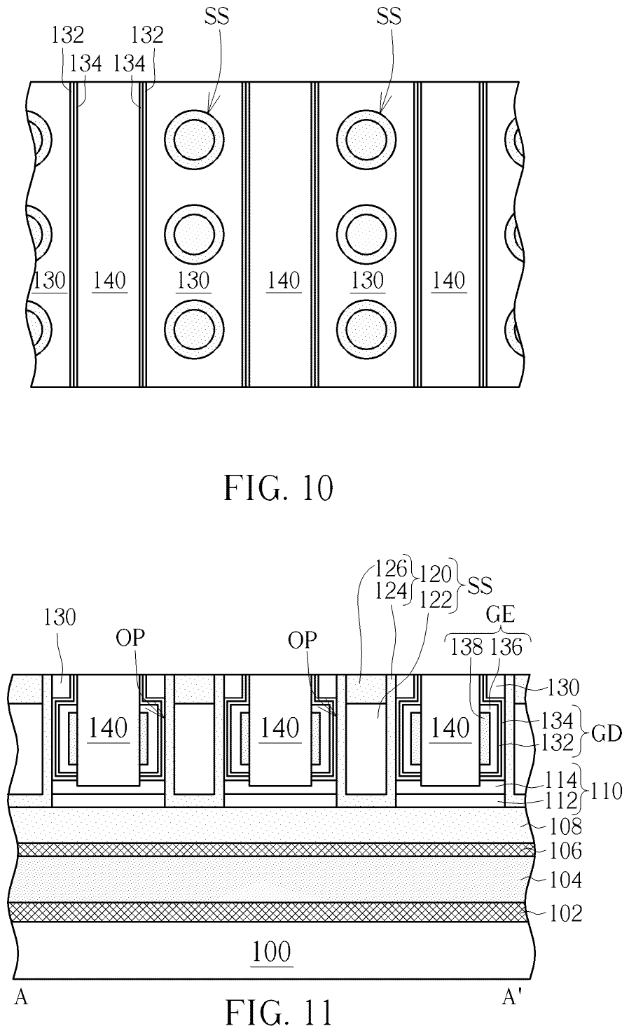

As shown in FIG. 10 and FIG. 11, a dielectric material layer (not shown in the drawings) is formed partially within the through hole R3, and partially outside the through hole R3, and then a planarization process such as a chemical polishing process or other suitable approaches is then performed, to remove the dielectric material layer outside the through hole R3, and to form the insulating spacer 140 with the bottom surface lower than the gate dielectric layer GD. After that, the drain structure DE is formed on the channel structure SS and the supporting layer 130, and the top dielectric layer 146 is formed, to form the semiconductor device 10 as shown in FIG. 1. Then, the fabrication of the semiconductor device 10 is accomplished thereby.

According to the fabricating method of the present disclosure, the channel structure SS is formed before forming the gate structure GE, and the supporting layer 130 is additionally formed on the sidewall of the channel structure SS, so that, the formation of the gate structure GE may be carried out by performing the etching process through the supporting layer 130. Then, the gate dielectric layer GD formed subsequently enables to be around the gate structure GE, conformally overlaying the supporting layer 130 and the lower sidewall of the channel structure SS, to present in a spoon-shaped cross-section thereby. In this way, the gate dielectric layer GD is formed between the gate structure GE and the channel structure SS in the horizontal direction D2/D3, and is formed partially between the supporting layer 130 and the gate structure GE and partially between the gate structure GE and the bottom dielectric layer 110 in the vertical direction D1, to gain the improved stability and better performance to the gate structure GE. Thus, the semiconductor device 10 fabricated according to the fabricating method of the present embodiment will therefore obtain the gate structure GE and the channel structure SS with better function and performance, so as to provide better operation.

People in the art should fully realize that the semiconductor device and the fabricating method thereof are not limited to the aforementioned embodiment and may include other examples or may be achieved through other strategies to meet practical product requirements. The following description will detail the different embodiments of the semiconductor device and fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

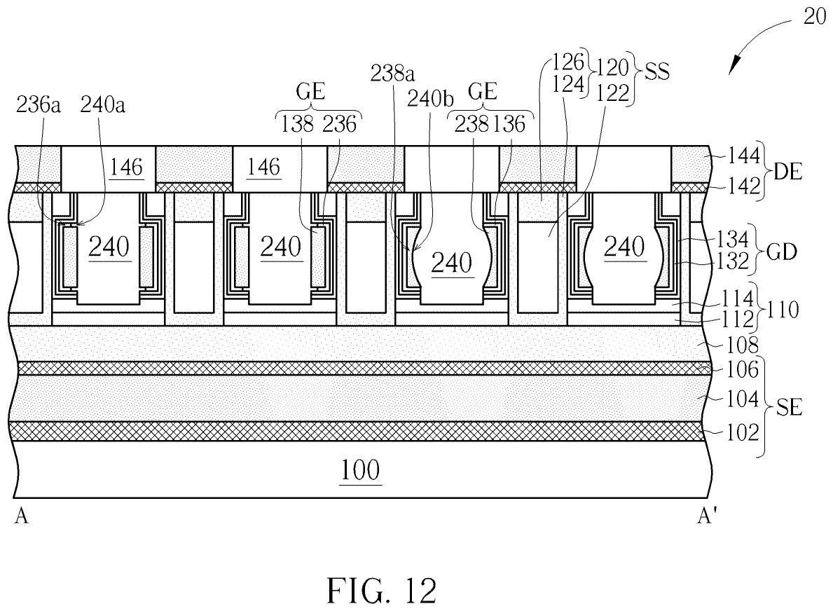

Please refer to FIG. 12, illustrating a schematic diagram of a cross-sectional view of a semiconductor device 20 according to the second embodiment of the present disclosure. As shown in FIG. 12, the structure of the semiconductor device 20 according to the present embodiment is substantially the same as the structure of the semiconductor device 10 according to the aforementioned first embodiment, which also including the source structure SE, the drain structure DE, the gate structure GE, the channel structure SS, the supporting layer 130, and the gate dielectric layer GD, and all similarities will not be redundantly described hereinafter. The semiconductor device 20 of the present embodiment and the aforementioned first embodiment is mainly in that while forming the through hole R3 as shown in FIG. 9, the etching conditions of the barrier material layer 136a and the conductive material layer 138a are adjusted, so that the etching degrees of the barrier material layer 136a and the conductive material layer 138a are different, so as to form at least one recessing portion 236a and at least one recessing portion 238a on the gate structure GE, with the at least one recessing portion 236a and the at least one recessing portion 238a being recessed toward the channel structure SS.

Precisely speaking, in one embodiment, the etching selectivity of the barrier material layer 136a related to the conductive material layer 138a is adjusted, so that, the etching degree of the barrier material layer 136a is therefore greater than that of the conductive material layer 138a, so as to form a barrier layer 236 with the recessing portion 236a, as shown in FIG. 12 at the left. The recessing portion 236a is for example formed between the gate layer 138 and the supporting layer 130, or between the bottom dielectric layer 110 and the gate layer 138, at the end of the gate structure GE. Then, an insulating spacer 240 formed subsequently will include a protrusion 240a filled in the recessing portion 236a correspondingly, at the end of the gate structure GE. In another embodiment, the etching selectivity of the conductive material layer 138a related to the barrier material layer 136a is adjusted, and the etching degrees of the conductive material layer 138a is greater than that of the barrier material layer 136a, so as to form a gate layer 238 with the recessing portion 238a, as shown in FIG. 12, at the right side. The recessing portion 238a is for example formed in the middle portion of the gate structure GE in the vertical direction D1, and the insulating spacer 240 formed subsequently will include a protrusion 240b filled in the recessing portion 238a correspondingly, at the middle portion of the gate structure GE.

Through these arrangements, the semiconductor device 20 fabricated according to the fabricating method of the present embodiment also includes the gate dielectric layer GD overlaying on the sidewall of the supporting layer 130, and being disposed around the gate structure GE, to improve the structural stability of the gate structure GE and the channel structure SS, and to enhance the operation and performance thereby.

Overall speaking, according to the semiconductor device and the fabricating method thereof, the channel structure is formed before the gate structure is formed, and the supporting layer is additionally formed on the sidewall of the channel structure, so that, the fabrication of the gate structure is allowable to be carried out by performing an etching process through the supporting layer, and the gate dielectric layer formed subsequently enables to be disposed around the gate structure, thereby conformally overlaying the supporting layer and the lower sidewall of the channel structure to present in a spoon-shaped cross-section. In this way, the gate dielectric layer is capable of providing improved stability and better functions to the gate structure, so as to enhance the operation of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a source structure;
a drain structure, the source structure and the drain structure stacked in a vertical direction;
a gate structure disposed between the drain structure and the source structure;
a channel structure, partially disposed in the gate structure and electrically connected the drain structure and the source structure;
a supporting layer, disposed on a sidewall of the channel structure; and
a gate dielectric layer, partially disposed between the channel structure and the gate structure in a horizontal direction, and partially disposed between the supporting layer and the gate structure.

2. The semiconductor device according to claim 1, wherein the gate dielectric layer physically contacts a top surface, a bottom surface and a sidewall of the gate structure.

3. The semiconductor device according to claim 1, wherein the gate dielectric layer physically contacts a bottom surface and a sidewall of the supporting layer.

4. The semiconductor device according to claim 1, further comprising:
an insulating spacer, disposed between the gate structure and the source structure, wherein the gate dielectric layer is partially disposed between the supporting layer and the insulating spacer.

5. The semiconductor device according to claim 4, wherein the insulating spacer and the supporting layer comprise different materials.

6. The semiconductor device according to claim 4, wherein a bottom surface of the insulating spacer is lower than a bottom surface of the gate dielectric layer.

7. The semiconductor device according to claim 4, wherein the insulating spacer comprises at least one protrusion extending toward the gate structure.

8. The semiconductor device according to claim 1, wherein the gate structure further comprises at least one recessing portion being recessed toward the channel structure.

9. The semiconductor device according to claim 7, wherein the at least one recessing portion is disposed on a top of the gate structure in the vertical direction.

10. The semiconductor device according to claim 7, wherein the at least one recessing portion is disposed at a middle portion of the gate structure in the vertical direction.

11. The semiconductor device according to claim 1, further comprising:
a bottom dielectric layer, disposed between the source structure and the gate structure, wherein the channel structure is partially disposed within the bottom dielectric layer, and the bottom dielectric layer and the supporting layer comprise a same material.

12. The semiconductor device according to claim 11, wherein the gate dielectric layer is partially disposed between the gate structure and the bottom dielectric layer in the vertical direction.

13. A fabricating method of a semiconductor device, comprising:
sequentially forming a source structure, a gate structure and a drain structure in a vertical direction;
forming a channel structure between the drain structure and the source structure, the channel structure being partially disposed in the gate structure and electrically connected the drain structure and the source structure;
forming a supporting layer on a sidewall of the channel structure; and
forming a gate dielectric layer between the channel structure and the gate structure, the gate dielectric layer being further formed between the supporting layer and the gate structure.

14. The fabricating method of forming the semiconductor device according to claim 13, wherein after forming the channel structure and the supporting layer, the gate dielectric layer and the gate structure are formed.

15. The fabricating method of forming the semiconductor device according to claim 13, further comprising:
forming an insulating spacer between the gate structure and the drain structure, wherein the gate dielectric layer is further formed between the supporting layer and the insulating spacer.

16. The fabricating method of forming the semiconductor device according to claim 15, wherein the insulating spacer comprises at least one protrusion extending toward the gate structure.

17. The fabricating method of forming the semiconductor device according to claim 13, wherein the gate structure further comprises at least one recessing portion being recessed toward the channel structure.

18. The fabricating method of forming the semiconductor device according to claim 15, further comprising:
forming a bottom dielectric layer between the source structure and the gate structure, wherein the channel structure is partially formed within the bottom dielectric layer.

19. The fabricating method of forming the semiconductor device according to claim 18, forming the channel structure further comprising:
sequentially forming a sacrificial layer and a supporting material layer stacked in sequence on the bottom dielectric layer;
partially removing the supporting material layer, the sacrificial layer, and the bottom dielectric layer, to form an opening penetrating through the supporting material layer, the sacrificial layer and the bottom dielectric layer;
forming the channel structure in the opening; and
after forming the channel structure, completely removing the sacrificial layer.

20. The fabricating method of forming the semiconductor device according to claim 19, wherein the sacrificial layer and the supporting material layer comprise different insulating materials, and the sacrificial layer and the insulating spacer comprise a same insulating material.
